(19) United States
(12) Patent Application Publication
(10) Pub. No.: US 2026/0304595 A1
(43) Pub. Date: Oct. 1, 2026

(54) FIXING STRUCTURE FOR ELECTRONIC MODULE AND ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/478,835

(22) PCT Filed: Apr. 17, 2024
(86) PCT No.: PCT/JP2024/015217

§ 371 Date: Oct. 27, 2025

(30) Foreign Application Priority Data
Apr. 28, 2023 (JP) 2023-074803

(51) Int. Cl. H05K 1/02; H01R 12/55; H05K 1/181

(52) U.S. Cl. CPC H05K 1/0204; H01R 12/55; H05K 1/181; H05K 2201/066; H05K 2201/0753; H05K 2201/10166; H05K 2201/10409; H05K 2201/10522

(57) ABSTRACT

A fixing structure for an electronic module is a fixing structure for fixing an electronic module that includes a first terminal and a first external connection member to a heat dissipation member by a first bolt. The first terminal is disposed on an surface on a side opposite to a surface that is brought into contact with the heat dissipation member in the electronic module, and has a first hole through which the first bolt is inserted, and a first insulation member that has a hole that allows a threaded portion of the first bolt to pass therethrough is disposed between the first bolt and the first external connection member and between the first bolt and the first terminal.

### CROSS REFERENCE

This application is a National Phase of International Application No. PCT/JP2024/015217 filed Apr. 17, 2024, which claims priority based on Patent Application 2023-074803 filed in Japan on Apr. 28, 2023, and the entire contents of the application are incorporated herein by reference.

### TECHNICAL FIELD

The present invention relates to a fixing structure for an electronic module, and an electronic module.

### BACKGROUND ART

Conventionally, at the time of fixing an electronic module to the inside of a machine device, there have been proposed a technique where the electronic module is mounted by a bolt, and a technique where an electronic module is mounted using leaf springs such as transistor clips. On the other hand, along with a demand for a large current to be used in an electronic module, a technique has been proposed where an external connection member is fixed to a terminal by a bolt thus securing the electrical conduction between a terminal and an external connection member with certainty (patent literature 1, patent literature 2).

FIG. 5 is a perspective view illustrating an electronic module 900 that is used in a fixing structure of an electronic module according to the prior art. In patent literature 1, as illustrated in FIG. 5, the description is made with respect to the electronic module 900 including a base board 940 used for fixing the electronic module 900 to a member on which the electronic module 900 is to be mounted by screwing, and mounting holes 942 disposed in the base board 940. The electronic module 900 further includes terminals 910, 920, 930. Bolt passing-through holes 912, 922, 932 are formed in the terminals 910, 920, 930 respectively. Nut arrangement holes are formed below the terminals 910, 920, 930, and electrically conductive nuts 914, 924, 934 are accommodated in the nut arrangement holes. An external connection member is disposed on each of the terminals 910, 920, 930, and the external connection member is fixed to each of the terminals 910, 920 and 930 by making bolts not illustrated in the drawing and the electrically conductive nuts 914, 924, 934 engage with each other by threaded engagement.

### PRIOR ART LITERATURE

### Patent Literature

[Patent literature 1] JP-A-2017-45772

[Patent literature 2] WIPO 2016/204306

### SUMMARY OF INVENTION

### Technical Problem

However, in a case where mounting of an external connection member on terminals is performed by screwing, places where an electronic module is fixed by screwing, and places where the external connection member is fixed to the terminal by screwing become necessary. Accordingly, such a fixing structure has a drawback that a size of the electronic module becomes large.

Therefore, it is an object of the present invention to provide a fixing structure for an electronic module capable of preventing a size of the electronic module from becoming large even in a case where the electronic module and an external connection member are fixed by screwing.

It is another object of the present invention to provide an electronic module capable of preventing a size of the electronic module from becoming large even in a case where the electronic module and an external connection member are fixed by screwing.

### Solution to Problem

A fixing structure for fixing an electronic module according to the present invention is a fixing structure for fixing an electronic module and a first external connection member to a heat dissipation member by a first bolt, the electronic module including a circuit, a first terminal, and a sealing resin that seals the circuit and a portion of the first terminal, wherein the first terminal is disposed on a surface opposite to a surface that is brought into contact with the heat dissipation member in the electronic module, and has a first hole through which the first bolt is inserted, and a first insulation member having a hole that allows a threaded portion of the first bolt to pass therethrough is disposed between the first bolt and the first external connection member and between the first bolt and the first terminal.

An electronic module according to the present invention is an electronic module that is fixed to a heat dissipation member together with a first external connection member by a first bolt, the electronic module including a circuit, a first terminal and a sealing resin that seals the circuit and a portion of the first terminal, wherein the first terminal is disposed on a surface opposite to a surface that is brought into contact with the heat dissipation member in the electronic module, and has a first hole through which the first bolt is inserted, and an inner peripheral portion of the first hole is brought into contact with an outer peripheral portion of a first insulation member disposed between the first bolt and the first terminal when the electronic module and the first external connection member are fixed to the heat dissipation member.

### Advantageous Effects of Invention

The fixing structure for the electronic module of the present invention fixes the electronic module and the first external connection member to the first terminal by the first bolt. Further, by arranging the first insulation member between the first bolt and the first external connection member, and between the first bolt and the first terminal, it is possible to secure insulation between the external connection member and the heat dissipation member.

According to the fixing structure of an electric module according to the present invention, the electronic module and the first external connection member can be fixed to the heat dissipation member by the first bolt. With such a configuration, in the electronic module, it is unnecessary to secure a place where the electronic module is fixed by screwing and a place where the external connection member is connected to the terminal by a screw individually. Accordingly, even in a case where an electronic module and an external connection member are fixed by screwing, it is possible to prevent a size of the electronic module from becoming large. Further, it is possible to secure insulation between the external connection member and the heat dissipation member by the first insulation member.

That is, it is possible to provide a fixing structure of an electronic module that can prevent a size of the electronic module from becoming large even in a case where the electronic module and an external connection member are fixed to the heat dissipation member by screwing.

Also in the electronic module according to the present invention, in the same manner as the fixing structure of an electronic module described above, the electronic module and the first external connection member can be fixed to the heat dissipation member. Further, the insulation between the external connection member and the heat dissipation member can be secured by the first insulation member. That is, even in a case where the electronic module and the external connection member are fixed to each other by screwing, it is possible to provide an electronic module capable of preventing a size of the electronic module from becoming large.

### BRIEF DESCRIPTION OF DRAWINGS

FIG. 1 is perspective view of a fixing structure 10 for an electronic module according to an embodiment.

FIG. 2 is a perspective view illustrating an electronic module 100 included in the fixing structure 10 for an electronic module according to the embodiment.

FIG. 3 is view illustrating the internal structure of the electronic module 100.

FIG. 4 is a cross-sectional view illustrating the fixing structure 10 of the electronic module according to the embodiment.

FIG. 5 is a perspective view illustrating an electronic module 900 used in a fixing structure for an electronic module according to a prior art.

### DESCRIPTION OF EMBODIMENTS

Hereinafter, a mode for carrying out a fixing structure for an electronic module and an electronic module according to the present invention is described. An embodiment described hereinafter is not intended to limit the invention called for in claims. Further, it is not always the case that various elements and all combinations of these elements described in the embodiment are indispensable for the present invention.

### 1. Fixing Structure for Electronic Module

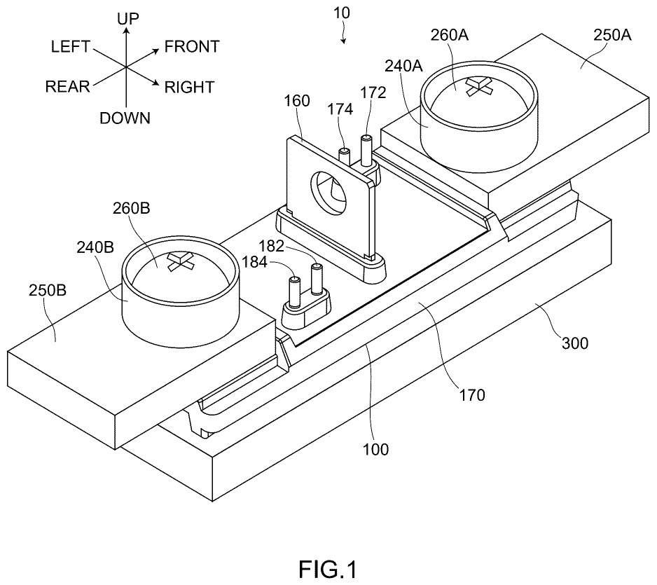

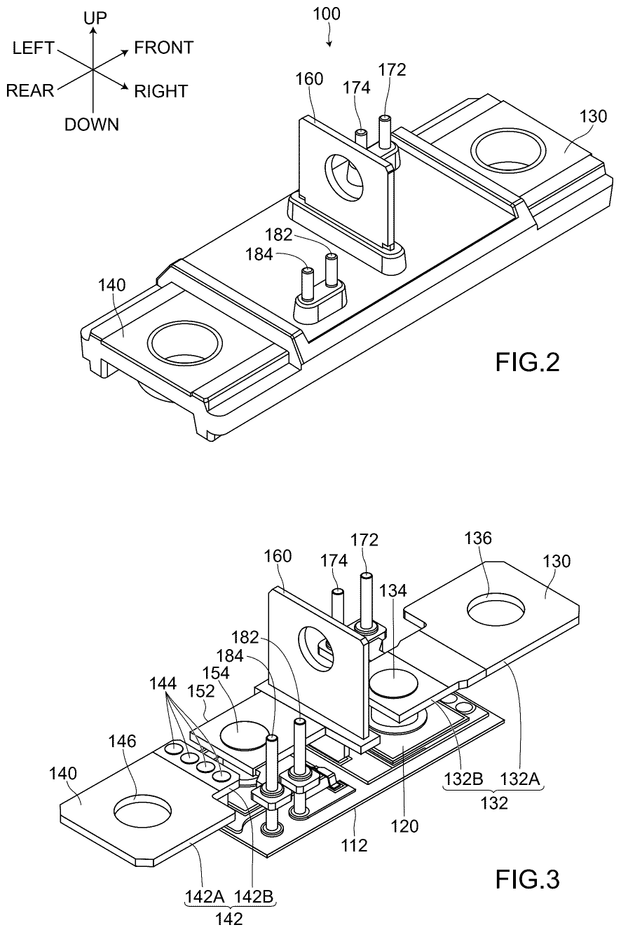

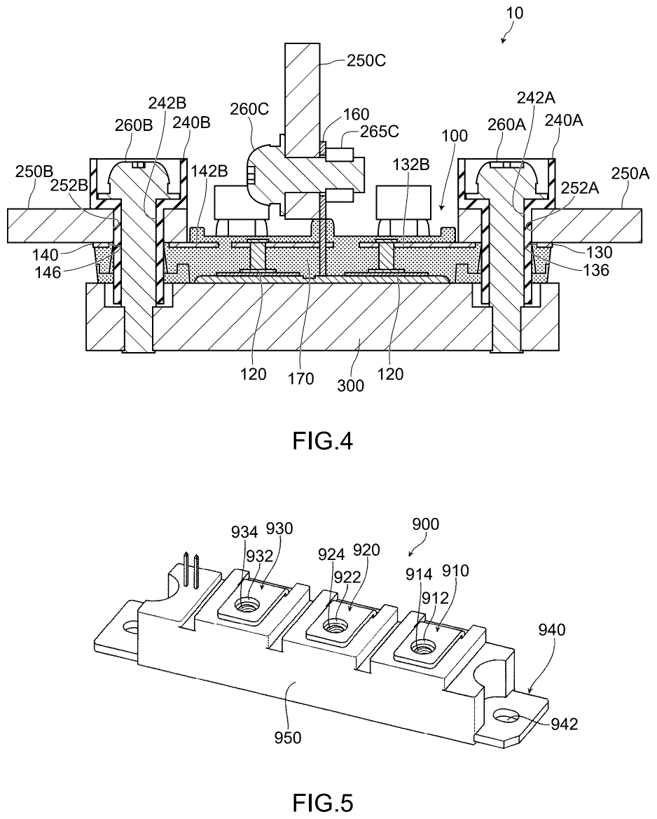

FIG. 1 is perspective view of a fixing structure 10 for an electronic module according to an embodiment. FIG. 2 is a perspective view illustrating an electronic module 100 included in the fixing structure 10 for an electronic module according to the embodiment. FIG. 3 is view illustrating the internal structure of the electronic module 100. FIG. 4 is a cross-sectional view illustrating the fixing structure 10 of the electronic module according to the embodiment.

In the description made hereinafter, as

illustrated in FIG. 1 and FIG. 2, the description is made by setting a longitudinal direction of the electronic module 100 as a front-rear direction, and a lateral direction as a left-and-right direction. Further, the description is made by setting a height direction of the electronic module 100 as an up-down direction. The terms “front”, “rear”, “left”, “right”, “up” and “down” in the description made hereinafter are used for the sake of convenience of the description, and do not specify the direction that the electronic module 100 is mounted when the electronic module 100 is used.

The fixing structure 10 of an electronic module according to the embodiment includes: the electronic module 100, a first external connection member 250A, a second external connection member 250B, a first bolt 260A, a second bolt 260B, a first insulation member 240A, and a second insulation member 240B. The fixing structure 10 of an electronic module fixes the electronic module 100 to a heat dissipation member 300. In the fixing structure 10 of an electronic module, the electronic module 100 is fixed to the heat dissipation member 300. In the fixing structure 10 of an electronic module, the first external connection member 250A is fixed to a first terminal 130 of the electronic module 100 by the first bolt 260A, and the second external connection member 250B is fixed to a second terminal 140 of the electronic module 100 by the second bolt 260B.

In the description made hereinafter, either one of “first external connection member 250A” and “second external connection member 250B” or both of these connection members may also be referred to as “external connection member 250” or either one of “first bolt 260A” and “second bolt 260B” or both of these bolts may also be referred to as “bolt 260”.

Hereinafter, the description is made in detail with respect to the fixing structure 10 of an electronic module, and the electronic module 100 that constitutes one of constitutional elements of the fixing structure 10 of an electronic module.

As illustrated in FIG. 1 to FIG. 4 the electronic module 100 is elongated in the front-rear direction, and is formed in an approximately rectangular parallelepiped body shape that is flat in the up-down direction. The electronic module 100 includes a circuit 120, the first terminal 130, the second terminal 140, a first wiring 132B, a second wiring 142B, signal terminals 172, 174, 182, 184, and a sealing resin 170.

In the description made hereinafter, either one or both of “the first terminal 130, the second terminal 140” may be also referred to as “terminals 130, 140”.

The circuit 120 includes wirings and elements. The element is, for example, a power metal-oxide-semiconductor field-effect transistor (MOSFET).

A circuit board 112 is, for example, a direct copper bonding (DCB) board where the circuit 120 is formed on one side surface of a ceramic board, and metal for dissipating heat is formed on the other side surface of the ceramic board. The circuit board 112 may be a printed circuit board or the like. It is desired that the circuit board 112 is formed in a rectangular flat plate shape, and is disposed at a center portion of the electronic module 100 in the front-rear direction that is the longitudinal direction.

As illustrated in FIG. 2 to FIG. 4, the first terminal 130 is disposed on a front side of the electronic module 100 in the front-rear direction. The first terminal 130 is constituted of a plate member 132A formed of a flat plate member having electrical conductivity, for example, a copper plate. The first terminal 130 has a first hole 136 that penetrates the first terminal 130 in the up-down direction. The first hole 136 has, for example, a circular shape as viewed in the up-down direction. The shape of the first hole 136 is not limited to a circular shape, and may be a polygonal shape such as a quadrangular shape or a hexagonal shape.

The first wiring 132B is electrically connected to the first terminal 130. The first wiring 132B is embedded in the sealing resin 170.

In the electronic module 100, the first wiring 132B integrally formed using the same plate member 132 as the first terminal 130. That is, a portion of the plate member 132 that is embedded in the sealing resin 170 corresponds to the first wiring 132B.

The first wiring 132B has a through hole (symbol being omitted) that vertically penetrates the first wiring 132B. The through hole is formed in a circular shape as viewed in the up-down direction. An upper end portion of an internal connection electrode 134 engages with the through hole by fitting engagement. The first wiring 132B and an electrode (symbol being omitted) of the circuit 120 are connected to each other by the internal connection electrode 134. The internal connection electrode 134 is fixed to the first wiring 132B by press fitting, for example.

As illustrated in FIG. 1 to FIG. 4, the second terminal 140 is disposed on a rear side of the electronic module 100 in the front-rear direction. The second terminal 140 is constituted of a plate member 142A formed of a flat plate member having electrical conductivity, for example, a copper plate. The second terminal 140 has a second hole 146 that penetrates the second terminal 140 in the up-down direction. The second hole 146 has, for example, a circular shape as viewed in the up-down direction. The shape of the second hole 146 is not limited to a circular shape, and may be a polygonal shape such as a quadrangular shape or a hexagonal shape.

The second wiring 142B is electrically connected to the second terminal 140. The second wiring 142B is embedded in the sealing resin 170.

In the electronic module 100, the second wiring 142B is integrally formed using the same plate member 142 as the second terminal 140. That is, a portion of the plate member 142 that is embedded in the sealing resin 170 corresponds to the second wiring 142B.

The second wiring 142B has four through holes (symbol being omitted) that penetrate the second wiring 142B in the up-down direction. The through hole is formed in a circular shape as viewed in the up-down direction. An upper end portion of an internal connection electrode 144 engages with the each of four through holes by fitting engagement. The second wiring 142B and electrodes (not illustrated in the drawing) of the circuit 120 are connected to each other by four internal connection electrodes 144. The internal connection electrode 144 is fixed to the second wiring 142B by press fitting, for example. The number of the above-mentioned through holes and the number of the above-mentioned internal connection electrodes 144 can be set to an arbitrary number of one or more without being limited to four provided that the flow of required electricity is allowed.

The electronic module 100 may include a third terminal 160. The third terminal 160 is an arbitrary constitutional element. As illustrated in FIG. 1 to FIG. 4, the third terminal 160 is formed of a flat plate member having electrical conductivity, for example, a copper plate. The third terminal 160 is arranged such that a plate thickness direction is the front-rear direction, and is formed in an elongated shape with the upper-down direction set as the longitudinal direction. The third terminal 160 has a portion that is exposed from the sealing resin 170 (hereinafter referred to as “upper side portion”), and a portion covered by the sealing resin 170 (hereinafter referred to as “lower side portion”).

A through hole (symbol being omitted) that penetrates in the longitudinal direction of the third terminal 160 is formed in an upper side portion of the third terminal 160. With such a configuration, as illustrated in FIG. 4, a third external connection member 250C can be fixed to the third terminal 160 by a bolt 260C and a nut 265C. Accordingly, it is possible to secure an electrical connection between the third terminal 160 and the third external connection member 250C with certainty.

A lower-side portion of the third terminal 160 is connected to an electrode (symbol being omitted) of the circuit 120.

The electronic module 100 may include a third wiring 152. The third wiring 152 is an arbitrary constitutional element. The third wiring 152 is electrically connected to the third terminal 160. The third wiring 152 may be disposed on the same plane as the first wiring 132B and the second wiring 142B.

The third wiring 152 has a through hole (symbol being omitted) that penetrates the third wiring 152 in the up-down direction. The through hole has a circular shape as viewed in the up-down direction. An upper end portion of the internal connection electrode 154 engages with the through hole by fitting engagement. The third wiring 152 and an electrode (symbol being omitted) of the circuit 120 are connected to each Other by the internal connection electrode 154. The internal connection electrode 154 is fixed to the third wiring 152 by press fitting, for example.

The electronic module 100 includes signal terminals 172, 174, 182, 184. The signal terminals 172, 174, 182, 184 are arbitrary constitutional elements. As illustrated in FIG. 3, each of the signal terminals 172, 174, 182, 184 includes: a pin terminal (symbol being omitted) formed in a columnar shape, for example, a circular columnar shape; and a support member (symbol being omitted) that is formed in a flat plate shape and supports the pin terminal. The support member is manufactured by applying press forming to a flat-plate-shape member having electrical conductivity, for example, a copper plate.

The signal terminals 172, 174, 182, 184 are disposed so as to protrude upward from the sealing resin 170. Each of signal terminals 172, 174, 182, 184 includes: a portion exposed from the sealing resin 170; and a portion covered by the sealing resin 170. Portions of the signal terminals 172, 174, 182, 184 covered by the sealing resin 170 are electrically connected to the electrodes of the circuit 120. The portion of the signal terminals 172, 174, 182, 184 exposed from the sealing resin 170 can be connected to external connection members not illustrated in the drawing.

As illustrated in FIG. 4, the sealing resin 170 seals the circuit 120, a lower surface of the first terminal 130, a lower surface of the second terminal 140, the first wiring 132B, and the second wiring 142B. Further, an inner peripheral portion of the first hole 136 and an inner peripheral portion of the second hole 146 may be also sealed by the sealing resin 170 thus forming the first hole 136 formed in the first terminal 130 as a first hole having a diameter smaller than the original first hole 136 by one size, and the second hole 146 formed in the second terminal 140 as a second hole having a diameter smaller than the original second hole 146 by one size (see FIG. 4). The sealing resin 170 is made of a thermosetting molding material obtained by adding a silica filler and the like to an epoxy resin that is a main component of the thermosetting resin material. The sealing resin 170 protects the circuit 120 from an environment such as heat, light, humidity and the like. A portion of the printed circuit board 112 may be exposed from the sealing resin 170. By exposing a surface of the printed circuit board 112 that opposedly faces the heat dissipation member 300 from the sealing resin 170, heat generated in the circuit 120 can be effectively dissipated to the heat dissipation member 300.

The sealing resin 170 has the through hole (symbol being omitted) through which a first bolt 260A passes, and a through hole (symbol being omitted) through which the second bolt 260B passes. The through hole is formed on a front side or a rear side of the electronic module 100 in the front-rear direction at a position where the first hole 136 is formed or the second hole 146 is formed. As viewed in the up-down direction, the through hole is formed in a circular shape, for example. The shape of the through hole is not limited to a circular shape, and may be a polygonal shape such as a quadrangular shape or a hexagonal shape. It is preferred that the shape and the size of the through hole may be approximately equal to the shape and size of the first hole 136 and the second hole 146.

With respect to the electronic module 100, as illustrated in FIG. 1 and FIG. 4, one surface of the electronic module 100 is mounted on the heat dissipation member 300 in a contact manner. In the fixing structure 10 of an electronic module 100, a surface of the electronic module 100 on a lower side in the drawing is brought into contact with the heat dissipation member 300. In the electronic module 100, the terminals 130, 140 are disposed on a surface disposed opposite to the surface that is brought into contact with the heat dissipation member 300.

The first external connection member 250A is disposed on an upper surface of the first terminal 130. The second external connection member 250B is disposed on an upper surface of the first terminal 140. The first external connection terminal 250A and the second external connection terminal 250B (hereinafter, either one of both of “first external connection member 250A” and “second external connection member 250B” also being referred to as “external connection member 250”) are each a plate member having conductive property, for example, a plate member formed of a copper plate. The external connection member 250 is also referred to as a bus bar (busbar) or the like.

### The First External Connection Member 250A

includes a third hole 252A that penetrates the first external connection member 250A in the up-down direction. When the first external connection member 250A is disposed on the upper surface of the first terminal 130, the third hole 252A is disposed at a position corresponding to the first hole 136. The third hole 252A has a circular shape, for example, when viewed in the up-down direction. The shape of the third hole 252A is not limited to a circular shape and may be a polygonal shape such as a quadrangular shape or a hexagonal shape. It is preferred that the shape and the size of the third hole 252A are substantially equal to the shape and the size of the first hole 136 formed in the first terminal 130.

### The Second External Connection Member 250B

includes a fourth hole 252B that penetrates the second external connection member 250B in the up-down direction. When the first external connection member 250A is disposed on the upper surface of the second terminal 140, the fourth hole 252B is disposed at a position corresponding to the second hole 146. The fourth hole 252B has a circular shape, for example, when viewed in the up-down direction. The shape of the fourth hole 252B is not limited to a circular shape and may be a polygonal shape such as a quadrangular shape or a hexagonal shape. It is preferred that the shape and the size of the fourth hole 252B are substantially equal to the shape and the size of the second hole 140 formed in the second terminal 140.

The first bolt 260A passes through the first hole 136, the third hole 252A, and a through hole formed in the sealing resin 170 of the electronic module 100. The second bolt 260B passes through the second hole 146, the fourth hole 252B, and a through hole formed in the sealing resin 170 of the electronic module 100.

The first bolt 260A and the second bolt 260B (hereinafter, either one of or both of “first bolt 260A and second bolt 260B” being referred to as “bolt 260” each include a threaded portion on which threads are formed, a head portion, a distal end portion (none of them indicated by symbols). Provided that the electronic module 100 can be fixed to the heat dissipation member 300, and the external connection members 250 can be fixed to the terminals 130, 140, fixing members other than the bolts 260 can be also used.

A portion of the bolt 260 close to a distal end of the threaded portion engages with threads formed in the hole (symbol being omitted) formed in the heat dissipation member 300 so as to enable fixing of the electronic module 100 and the external connection member 250 to the heat dissipation member 300. Alternatively, by allowing the distal end of the threaded portion to pass through the heat dissipation member 300 and by making the distal end of the threaded portion threadedly engage with a nut not illustrated in the drawing, the electronic module 100 and the external connection member 250 can be fixed to the heat dissipation member 300.

The first insulation member 240A has a hole 242A through which the threaded portion of the first bolt 260A passes. A diameter of the hole 242A is set larger than a diameter of the threaded portion of the first bolt 260A and is set smaller than the head portion of the first bolt 260A. Further, the first insulation member 240A is disposed between the first bolt 260A and the first external connection member 250A and between the first bolt 260A and the first terminal 130.

As illustrated in FIG. 4, to be more specific, the first insulation member 240A includes: a cylindrical portion that extends in the up-down direction and has the hole 242A that allows the first bolt 260A to pass therethrough; and a disk-shaped portion having a center portion where the hole 242A that allows the first bolt 260A to pass through is formed. In the first insulation member 240A, the cylindrical portion is disposed between the threaded portion of the first bolt 260A and the first external connection member 250A, and between the threaded portion of the first bolt 260A and the first terminal 130. Further, the disk-shaped portion is disposed between the head portion of the first bolt 260A and the upper surface of the first external connection member 250A. With such a configuration, the insulation can be secured between the first bolt 260A and the first external connection member 250A, and between the first bolt 260A and the first terminal 130.

It is preferred that the first insulation member 240A is configured to be disposed between the first bolt 260A and the sealing resin 170. To be more specific, the cylindrical portion of the first insulation member 240A that is disposed between the first bolt 260A and the first terminal 130 extends downward so that the first insulation member 240A is disposed also between the first bolt 260A and the sealing resin 170. With such a configuration, the insulation can be secured between the first bolt 260A and an internal wiring of the electronic module 100 with more certainty.

It is desired that the first insulation member 240A is configured to be disposed around the head portion of the first bolt 260A. To be more specific, as illustrated in FIG. 1 and FIG. 4, the first insulation member 240A has a cylindrical portion that is disposed around the head portion of the first bolt 260A, and extends in the up-down direction. With such a configuration, the insulation of the first bolt 260A can be secured with more certainty.

The second insulation member 240B has a hole 242B through which the threaded portion of the second bolt 260B passes. A diameter of the hole 242B is set larger than a diameter of the threaded portion of the second bolt 260B and is set smaller than the head portion of the second bolt 260B. Further, the second insulation member 240B is disposed between the second bolt 260B and the second external connection member 250B and between the second bolt 260B and the second terminal 140.

As illustrated in FIG. 4, to be more specific, the second insulation member 240B includes: a cylindrical portion that extends in the up-down direction and has the hole 242B that allows the second bolt 260B to pass therethrough; and a disk-shaped portion having a center portion where the hole 242B that allows the second bolt 260B to pass through is formed. In the second insulation member 240B, the cylindrical portion is disposed between the threaded portion of the second bolt 260B and the second external connection member 250B, and between the threaded portion of the second bolt 260B and the second terminal 140. Further, the disk-shaped portion is disposed between the head portion of the second bolt 260B and the upper surface of the second external connection member 250B. With such a configuration, the insulation can be secured between the second bolt 260B and the second external connection member 250B, and between the second bolt 260B and the second terminal 140.

It is preferred that the second insulation member 240B is configured to be disposed between the second bolt 260B and the sealing resin 170. To be more specific, the cylindrical portion of the second insulation member 240B that is disposed between the second bolt 260B and the second terminal 140 extends downward so that the second insulation member 240B is disposed also between the second bolt 260B and the sealing resin 170. With such a configuration, the insulation can be secured between the second bolt 260B and an internal wiring of the electronic module 100 with more certainty.

It is desired that the second insulation member 240B is configured to be disposed around the head portion of the second bolt 260B. To be more specific, as illustrated in FIG. 1 and FIG. 4, the second insulation member 240B has a cylindrical portion that is disposed around the head portion of the second bolt 260B, and extends in the up-down direction. With such a configuration, the insulation of the second bolt 260B can be secured with more certainty.

It is preferred that an a outer peripheral portion of each of the first insulation member 240A and the second insulation member 240B (hereinafter, also referred to as either one of “first insulation member 240A” and “second insulation member 240B” or “insulation member 240” indicating both insulation members 240A, 240B) is configured to be brought into contact with an inner peripheral portion of the first hole 136 or an inner peripheral portion of the second hole 146. Further, it is preferred that the outer peripheral portion of the insulation member 240 is brought into contact with an inner peripheral portion of the second hole 146 or an inner peripheral portion of the fourth hole 252B. Still further, it is preferred that the outer peripheral portion of the insulation member 240 is brought into contact with the inner peripheral portion of the through hole formed in the ceiling resin 170. With such a configuration where the outer peripheral portion of the insulation member 240 is brought into contact with the inner peripheral portion of the first hole 136, the inner peripheral portion of the second hole 146, the inner peripheral portion of the third hole 252A, the inner peripheral portion of the fourth hole 252B or the through hole formed in the sealing resin 170, it is possible to support the insulation member 240 in a stable manner.

A material that is used for forming the insulation member 240 is not limited provided that the material has an insulation property. However, it is preferred that the insulation member 240 is formed using at least one material selected from a group of materials consisting of a resin, silicon and ceramic. As the resin, a fluoric resin such as polytetrafluoroethylene or a thermoplastic resin such as polyacetal (POM) and the like can be exemplified. By selecting the material that forms the insulation member 240 from the above-mentioned materials, it is possible to secure insulation between the external connection member 250, the bolt 260 and the heat dissipation member 300. It is also possible to use a material that is available in a market in the name of an insulation collar or the like.

In the above-mentioned embodiment, the description has been made with respect to the case where an element included in the circuit 120 is a power MOSFET. However, the element is not limited to a power MOSFET. Other semiconductor elements such as an IGBT, a thyristor, a diode, and the like may be also used as the circuit. As a material of the element, silicon, SiC, GaN and the like can be used. Further, the element may be an element other than a semiconductor element. For example, the element may be a capacitor, a reactor or the like.

In the fixing structure 10 for an electronic module described heretofore, the first terminal 130 of the electronic module 100 includes the first hole 136 that allows the first bolt 260A for fixing the electronic module 100 and the first external connection member 250A to the heat dissipation member 300 to pass therethrough. The fixing structure 10 also includes the first insulation member 240A having the hole 242A through which the threaded portion of the first bolt 160A is allowed to pass. With respect to the first insulation member 240A, the first insulation member 240A is disposed between the first bolt 260A and the first external connection member 250A, and between the first bolt 260A and the first terminal 130.

The electronic module 100 and the first external connection member 250A can be fixed to the heat dissipation member 300 by the first bolt 260A. Further, by interposing the first insulation member 240A between the first bolt 260A and the first external connection member 250A and between the first bolt 260A and the first terminal 130, it is possible to secure the insulation between the first external connection member 250A and the heat dissipation member 300.

That is, according to the fixing structure 10 of an electronic module, the electronic module 100 and the first external connection member 250A can be fixed to the heat dissipation member 300 by the first bolt 260A. Accordingly, it is unnecessary to secure a place where the electronic module 100 is fixed by screwing and a place where the external connection member 250A is connected to the first terminal by screwing individually. Further, it is possible to secure the insulation between the first external connection member 250A and the heat dissipation member 300 by the first insulation member 240A. That is, also in the case where the electronic module 100 and the first external connection member 250A are connected by screwing, it is possible to provide the fixing structure 10 of an electronic module that can be miniaturized while securing insulation property between the first external connection member 250A and the heat dissipation member 300.

### 2. Electronic Module

Next, the electronic module 100 according to the embodiment is described. The electronic module 100 according to the embodiment has the same structure as the electronic module 100 in the fixing structure 10 of an electronic module. In view of the above, the description of the electronic module 100 is made using FIG. 1 to FIG. 4 used in the description of the fixing structure of an electronic module, and the description of portions where the descriptions overlap with each other is omitted.

As illustrated in FIG. 1 to FIG. 4 the electronic module 100 is elongated in the front-rear direction, and is formed in an approximately rectangular parallelepiped body shape that is flat in the up-down direction. The electronic module 100 includes a circuit 120, a first terminal 130, and a sealing resin 170 that seals the circuit 120 and a lower surface of the first terminal 130. The electronic module 100 may include a second terminal 140.

The first terminal 130 and the second terminal 140, in the electronic module 100, are disposed on a surface opposite to a surface where the electronic module 100 is brought into contact with the heat dissipation member 300. That is, the first terminal 130 and the second terminal 140 are disposed on the surface of the electronic module 100 on an upper side in the up-down direction. The first terminal 130 has the first hole 136 through which the fist bolt 260A passes. The second terminal 140 has the second hole 146 through which the second bolt 260B passes.

As illustrated in FIG. 4, the sealing resin has a through hole (symbol being omitted) through which the first bolt 260A or the second bolt 260B passes. The through hole is formed on a front side or a rear side of the electronic module 100 in the front-rear direction at the position where the first hole 136 is formed or at the position where the second hole 146 is formed.

The electronic module 100 is mounted on the heat dissipation member 300 such that a lower surface of the electronic module 100 is brought into contact with the heat dissipation member 300. The electronic module 100 is fixed to heat dissipation member 300 together with the first external connection member 250A by the first bolt 260A. Further, the electronic module 100 may be fixed to the heat dissipation member 300 together with the second external connection member 250B by the second bolt 260B.

In fixing the electronic module 100, the first insulation member 240A is disposed between the first hole 136 and the first bolt 260A. The first insulation member 240A is formed of a cylindrical insulation member, for example. The first insulation member 240A has a hole 242A having a cross section that allows the first bolt 260A to pass through the first insulation member 240A. The hole 242A extends in the up-down direction in the drawing.

The first hole 136 is brought into contact with an outer peripheral portion of the first insulation member 240A. By adopting the configuration where the outer peripheral portion of the first insulation member 240A is brought into contact with the inner peripheral portion of the first hole 136, the first insulation member 240A can be supported in a stable manner.

The second insulation member 240B may be disposed between the second hole 146 and the second bolt 260B. The second insulation member 240B is formed of a cylindrical insulation member, for example. The second insulation member 240B has a hole 242B having a cross section that allows the second bolt 260B to pass through the second insulation member 240B. The hole 242B extends in the up-down direction in the drawing.

The second hole 146 is brought into contact with an outer peripheral portion of the second insulation member 240B. By adopting the configuration where the outer peripheral portion of the second insulation member 240B is brought into contact with the inner peripheral portion of the second hole 146, the second insulation member 240B can be supported in a stable manner.

In the electronic module 100, the first terminal 130 includes the first hole 136 through which the first bolt 260A provided for fixing the electronic module 100 and the first external connection member 250A to the heat dissipation member 300 passes through. With such a configuration, the electronic module 100 and the first external connection member 250A can be fixed to the heat dissipation member 300 using the first bolt 260A.

The first insulation member 240A is disposed between the first bolt 260A and the first hole 136. With such a configuration, it is possible to secure insulation between the first terminal 130 and the heat dissipation member 300. Further, the inner peripheral portion of the first hole 136 is brought into contact with an outer peripheral portion of the first insulation member 240A that is disposed between the first bolt 260A and the first hole 136. With such a configuration, the first insulation member 240A can be supported in a stable manner.

That is, according to the electronic module 100, the electronic module 100 can be fixed to the heat dissipation member 300 and the first external connection member 250A can be fixed to the first terminal 130 of the electronic module 100 while securing insulation property between the first external connection member 250A and the heat dissipation member 300. Accordingly, even in a case where the electronic module 100 is fixed by screwing and the first external connection member 250A is fixed to the first terminal 130 of the electronic module 100 by screwing, it is possible to provide the electronic module 100 capable of being miniaturized while ensuring insulation property between the first external connection member 250A and the heat dissipation member 300.

1. A fixing structure for fixing an electronic module and a first external connection member to a heat dissipation member by a first bolt, the electronic module including a circuit, a first terminal, and a sealing resin that seals the circuit and a portion of the first terminal, wherein
the electronic module has a first internal connection electrode, one end of which engages with the through hole by fitting engagement into a through hole formed in the first terminal and the other end of which is electrically connected to a wiring of the circuit,
the first terminal is disposed on a surface opposite to a surface that is brought into contact with the heat dissipation member in the electronic module, and has a first hole through which the first bolt is inserted, and
a first insulation member having a hole that allows a threaded portion of the first bolt to pass therethrough is disposed between the first bolt and the first external connection member and between the first bolt and the first terminal.

2. The fixing structure according to claim 1, wherein
the first insulation member is further disposed between the first bolt and the sealing resin, and around a head portion of the first bolt.

3. The fixing structure according to claim 1, wherein
an outer peripheral portion of the first insulation member is brought into contact with an inner peripheral portion of the first hole.

4. The fixing structure according to claim 1, wherein
the first insulation member is formed using one or more materials selected from a group consisting of a resin, silicon and ceramic.

5. The fixing structure according to claim 1, wherein
the fixing structure is a fixing structure for fixing the electronic module and a second external connection member to the heat dissipation member by a second bolt,
the electronic module includes a second terminal and a second internal connection electrode, the second terminal is disposed on a surface opposite to a surface that is brought into contact with the heat dissipation member in the electronic module, and has a second hole through which the second bolt is inserted,
one end of the second internal connection electrode engages with the through hole by fitting engagement into a through hole formed in the first terminal, and the other end thereof is electrically connected to a wiring of the circuit,
a second insulation member has a hole that allows a threaded portion of the second bolt to pass therethrough, and is disposed between the second bolt and the second external connection member, and between the second bolt and the second terminal, and
the first hole is disposed at one end portion of the electronic module when the electronic module is viewed in a plan view, and the second hole is disposed at the other end portion opposite to the one end portion.

6. An electronic module that is fixed to a heat dissipation member together with a first external connection member by a first bolt, the electronic module including a circuit, a first terminal and a sealing resin that seals the circuit and a portion of the first terminal, wherein
the electronic module has a first internal connection electrode, one end of which engages with the through hole by fitting engagement into a through hole formed in the first terminal and the other end of which is electrically connected to a wiring of the circuit,
the first terminal is disposed on a surface opposite to a surface that is brought into contact with the heat dissipation member in the electronic module, and has a first hole through which the first bolt is inserted, and
an inner peripheral portion of the first hole is brought into contact with an outer peripheral portion of a first insulation member disposed between the first bolt and the first terminal when the electronic module and the first external connection member are fixed to the heat dissipation member.
